(19) United States
(12) Patent Application Publication
(10) Pub. No.: US 2009/0242989 A1
(43) Pub. Date: Oct. 1, 2009

(54) COMPLEMENTARY METAL-OXIDE-SEMICONDUCTOR DEVICE WITH EMBEDDED STRESSOR

(76) Inventors: KEVIN K. CHAN, Staten Island, NY (US); Jack O. Chu, Manhasset Hills, NY (US); Jin-Ping Han, Fishkill, NY (US); Thomas S. Kanarsky, Hopewell Junction, NY (US); Hung Y. Ng, New Milford, NJ (US); Qiqing Quyang, Yorktown Heights, NY (US); Gen Pei, Mahopac, NY (US); Chun-Yung Sung, Poughkeepsie, NY (US); Henry K. Utomo, Newburgh, NY (US); Thomas A. Wallner, Pleasant Valley, NY (US)

Correspondence Address: WALL & TONG, LLP;IBM CORPORATION, 595 SHREWSBURY AVE, SUITE 100, SHREWSBURY, NJ, 07702, US

(21) Appl. No.: 12/054,933

(22) Filed: Mar. 25, 2008

(51) Int. Cl. H01L 29/78; H01L 21/336

(52) U.S. Cl. 257/351; 438/163; 438/154; 257/E29.295; 257/E21.409

(57) ABSTRACT

In one embodiment, the invention is a complementary metal-oxide-semiconductor device with an embedded stressor. One embodiment of a field effect transistor includes a silicon on insulator channel, a gate electrode coupled to the silicon on insulator channel, and a stressor embedded in the silicon on insulator channel and spaced laterally from the gate electrode, where the stressor is formed of a silicon germanide alloy whose germanium content gradually increases in one direction.

### BACKGROUND OF THE INVENTION

The present invention relates generally to integrated circuits (ICs), and relates more particularly to complementary metal-oxide-semiconductor (CMOS) devices that make use of strain-induced effects.

One of the most effective approaches to improving carrier mobility and transistor device current in CMOS devices makes use of strain-induced effects. For instance, employing a boron-doped silicon germanide alloy (SiGe) “stressor” in the source and drain region of a p-type field effect transistor (pFET) provides uniaxial compressive strain to the silicon channel. This strain has been shown to enhance the driving current (performance) of the pFET. The stressor is typically positioned in a recess outward of the silicon channel, where the source and drain would normally be located.

Use of the SiGe stressor, however, introduces other complications. For instance, the closer the stressor is positioned to the edge of the gate of the pFET, the more stress the stressor exerts on the silicon channel. However, if the stressor is positioned too close to the gate, it becomes necessary to remove at least some of the halo implant region in the silicon channel. The removal of even a portion of the halo implant region results in degraded transistor performance and short channel control, as boron dopants in the stressor diffuse into the silicon channel.

In addition, as illustrated in FIG. 1, which is a plot of the material characteristics of SiGe, as the germanium content of the SiGe increases, the critical thickness of the SiGe decreases (and the stressor therefore loses strain more quickly). This further results in defects and dislocations due to crystal lattice mismatch between the SiGe stressor and the silicon channel. Excessive defects result in transistor device leakage and degraded device performance.

Thus, there is a need in the art for a complementary metal-oxide-semiconductor device with an embedded stressor that improves the germanium content of the SiGe stressor and preserves the halo region.

### SUMMARY OF THE INVENTION

In one embodiment, the invention is a complementary metal-oxide-semiconductor device with an embedded stressor. One embodiment of a field effect transistor includes a silicon on insulator channel, a gate electrode coupled to the silicon on insulator channel, and a stressor embedded in the silicon on insulator channel and spaced laterally from the gate electrode, where the stressor is formed of a silicon germanide alloy whose germanium content gradually increases in one direction.

### BRIEF DESCRIPTION OF THE DRAWINGS

So that the manner in which the above recited features of the present invention can be understood in detail, a more particular description of the invention, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a plot of the material characteristics of silicon germanide; and

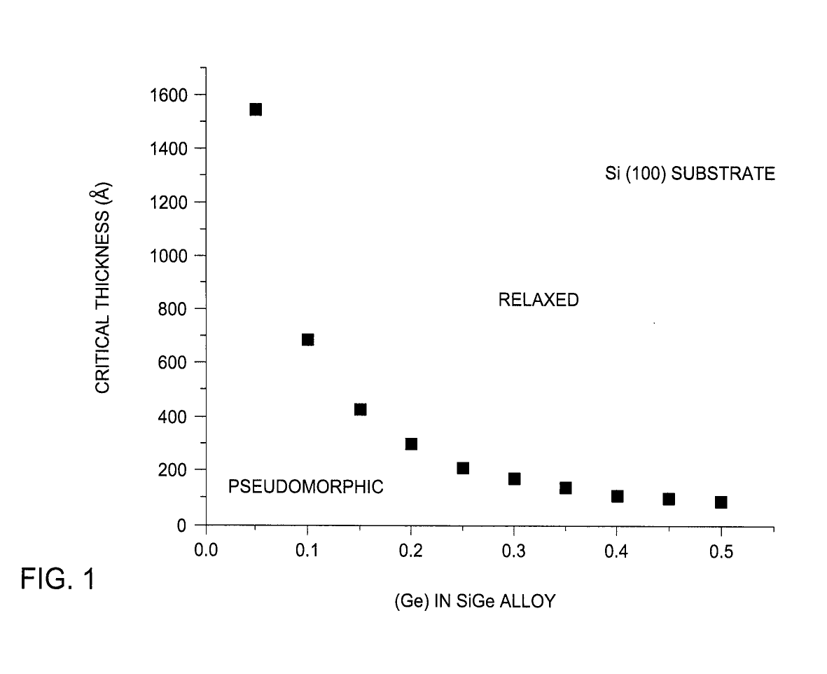

FIG. 2 is a schematic diagram illustrating one embodiment of a p-type field effect transistor with an embedded stressor, according to the present invention.

### DETAILED DESCRIPTION

In one embodiment, the present invention is a complementary metal-oxide-semiconductor device with an embedded stressor. Embodiments of the present invention improve the germanium content of the SiGe stressor in a pFET while preserving halo regions. Embodiments of the present invention may be further applied to silicon carbide (SiC) material used in nFETs.

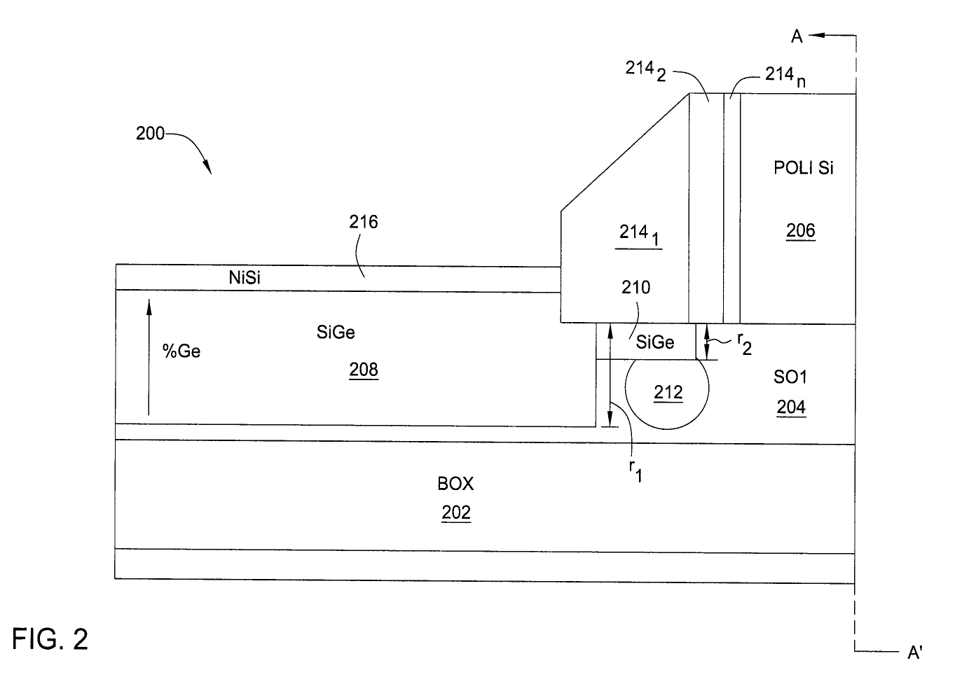

FIG. 2 is a schematic diagram illustrating one embodiment of a pFET 200 with an embedded stressor, according to the present invention. Specifically, FIG. 2 illustrates one half of the pFET 200, which has been cut along line A-A′.

As illustrated, the pFET 200 comprises a buried oxide (BOX) layer 202, a silicon on insulator (SOI) channel 204 disposed over the buried oxide layer 202, and a gate electrode 206 disposed over the SOI channel 204.

The SOI channel 204 further includes an embedded stressor 208, an extension 210, and a halo region 212. The stressor 208 is embedded in the SOI channel and is positioned laterally outward from the gate electrode 206 (which, in one embodiment, is formed of polysilicon). The stressor 208 is spaced from the gate electrode 206 by one or more spacers 214₁-214ₙ (hereinafter collectively referred to as “spacers 214”). A first recess r₁ is formed in the SOI channel 204 to accommodate the stressor 208. In one embodiment, the first recess r₁ has a depth of approximately 54 nm. In one embodiment, the stressor 208 is formed of epitaxially grown SiGe. In a further embodiment, the stressor 208 is graded such that the germanium content of the SiGe increases in one direction (e.g., from bottom to top, or in the direction moving away from the BOX layer 202 in FIG. 2). In one embodiment, germanium content of the SiGe ranges from a low of approximately 7.5% to a high of approximately 50%. In one embodiment, the stressor 208 is ion-implanted to supply electrons to the SOI channel 204 (via the extension 210, as described further below). In one embodiment, the stressor 208 is ion-implanted with boron. A nickel silicide (NiSi) layer 216 is deposited over the stressor 208.

The extension 210 is also embedded in the SOI channel 204 and is positioned between the edge of the stressor 208 and the edge of the gate electrode 206. A second recess r₂ is formed in the SOI channel 204 to accommodate the extension 210. In one embodiment, the second recess r₂ has a depth of approximately 25 nm. In one embodiment, the extension 210 is formed of epitaxially grown SiGe. In a further embodiment, the germanium content of the extension 210 is approximately 20%. In an alternative embodiment, the extension 210 is graded such that the germanium content gradually increases up to as much as approximately 50% in one direction. In one embodiment, the germanium content of the extension 210 is graded if the germanium content exceeds 20%. The extension 210 lowers the resistance for electrons to travel from the stressor 208 to the SOI channel 204. Moreover, the smaller depth of the second recess r₂ relative to the first recess r₁ provides a path for electrons flowing from the stressor 208 to the SOI channel 204 (via the extension 210) while preserving at least most of the halo implant region 212. In one embodiment, the extension 210 is ion-implanted to lower the resistance. In a further embodiment, the extension 210 is boron-doped.

The halo region 212 is also embedded in the SOI channel 204 and is positioned adjacent to the stressor 208, between the extension 210 and the BOX layer 202. The halo region 212 comprises one or more dopants. In one embodiment, these dopants include at least one of: boron and germanium. In a further embodiment, the halo region 212 is ion-implanted to prevent excessive diffusion of these dopants.

The construction of the pFET 200 provides a plurality of advantages over typical CMOS devices with embedded stressors. For instance, the use of an epitaxial boron-doped SiGe extension 210 between the stressor 208 and the SOI channel 204 provides low resistance and good stress to the SOI channel 204. Moreover, the depth of the second recess r₂ required to accommodate the extension 210 can be reduced and adjusted to improve short channel control. Because the extension 210 is grown epitaxially, the germanium content can be increased accordingly to exert more stress on the SOI channel 204. In addition, grading of the germanium content substantially ensures that the critical thickness of the SiGe is not exceeded.

Improved proximity between the stressor 208 and the edge of the gate electrode 206 can be achieved by growing an epitaxial boron-doped SiGe extension 210 driven by high-temperature annealing to produce a good boron dopant “linkup” to the SOI channel 204. This linkup may then be replaced with a boron-doped SiGe stressor 208.

The epitaxial boron-doped SiGe stressor 208 provides low resistance in the stressor region. Moreover, because the stressor 208 is positioned away from the extension 210, the halo implant region 212 is substantially preserved (i.e., the size of the halo implant region 212 is maximized). Additionally, by grading the germanium content of the stressor 208, higher germanium content can be achieved without exceeding the critical thickness of the SiGe, allowing more stress to be transferred to the SOI channel 204. The grading of the germanium content also allows for higher boron content near the surface of the stressor 208, which minimizes boron diffusion and enhances CMOS device performance.

While the foregoing is directed to embodiments of the present invention, other and further embodiments of the invention may be devised without departing from the basic scope thereof. Various embodiments presented herein, or portions thereof, may be combined to create further embodiments. Furthermore, terms such as top, side, bottom, front, back, and the like are relative or positional terms and are used with respect to the exemplary embodiments illustrated in the figures, and as such these terms may be interchangeable.

What is claimed is:

1. A field effect transistor, comprising:
a silicon on insulator channel;
a gate electrode coupled to the silicon on insulator channel; and
a stressor embedded in the silicon on insulator channel and spaced laterally from the gate electrode, the stressor comprising a silicon germanide alloy whose germanium content gradually increases in one direction.

2. The field effect transistor of claim 1, wherein a recess formed in the silicon on insulator channel to accommodate the stressor has a depth of approximately 54 nm.

3. The field effect transistor of claim 2, wherein the silicon germanide alloy is epitaxially grown in the recess.

4. The field effect transistor of claim 1, wherein the germanium content of the silicon germanide alloy ranges from a low of approximately 7.5 percent to a high of approximately 50 percent.

5. The field effect transistor of claim 1, wherein the stressor is ion-implanted with boron.

6. The field effect transistor of claim 1, further comprising:
a nickel silicide layer deposited over the stressor.

7. The field effect transistor of claim 1, further comprising:
a halo implant region embedded in the silicon on insulator channel and positioned adjacent to the stressor.

8. The field effect transistor of claim 7, wherein the halo implant region comprises at least one of: boron or germanium.

9. The field effect transistor of claim 7, further comprising:
an extension embedded in the silicon on insulator channel, the extension positioned to provide a path for electrons flowing from the stressor to the silicon on insulator channel while maximizing a size of the halo implant region.

10. The field effect transistor of claim 9, wherein a recess formed in the silicon on insulator channel to accommodate the extension has a depth of approximately 25 nm.

11. The field effect transistor of claim 9, wherein the extension is formed of a silicon germanide alloy.

12. The field effect transistor of claim 11, wherein the silicon germanide alloy is epitaxially grown in the recess

13. The field effect transistor of claim 11, wherein a germanium content of the silicon germanide alloy forming the extension gradually increases in one direction.

14. The field effect transistor of claim 13, wherein the germanium content of the silicon germanide alloy forming the extension is graded up to a maximum of approximately fifty percent.

15. The field effect transistor of claim 11, wherein a germanium content of the silicon germanide alloy forming the extension is approximately twenty percent.

16. The field effect transistor of claim 11, wherein the extension is ion-implanted with boron.

17. The field effect transistor of claim 1, wherein the field effect transistor is a p-type field effect transistor.

18. A method for fabricating a field effect transistor, comprising:
providing a silicon on insulator channel;
providing a gate electrode coupled to the silicon on insulator channel; and
embedding a stressor in the silicon on insulator channel, spaced laterally from the gate electrode, the stressor comprising a silicon germanide alloy whose germanium content gradually increases in one direction.

19. The method of claim 18, further comprising:
forming a recess having a depth of approximately 54 nm in the silicon on insulator channel to accommodate the stressor.

20. The method of claim 19, wherein the embedding comprises:
epitaxially growing the silicon germanide alloy in the recess.

21. The method of claim 18, wherein the germanium content of the silicon germanide alloy ranges from a low of approximately 7.5 percent to a high of approximately 50 percent.

22. The method of claim 18, further comprising:
ion-implanting the stressor with boron.

23. The method of claim 18, further comprising:
depositing a nickel silicide layer over the stressor.

24. The method of claim 18, further comprising:
embedding a halo implant region in the silicon on insulator channel, positioned adjacent to the stressor.

25. The method of claim 24, wherein the halo implant region comprises at least one of: boron or germanium.

26. The method of claim 24, further comprising:
embedding an extension in the silicon on insulator channel, the extension positioned to provide a path for electrons flowing from the stressor to the silicon on insulator channel while maximizing a size of the halo implant region.

27. The method of claim 26, further comprising:
forming a recess having a depth of approximately 25 nm in the silicon on insulator channel to accommodate the extension.

28. The method of claim 26, wherein the extension is formed of a silicon germanide alloy.

29. The method of claim 28, wherein embedding the extension comprises:
epitaxially growing the silicon germanide alloy in the recess

30. The method of claim 28, wherein a germanium content of the silicon germanide alloy forming the extension gradually increases in one direction.

31. The method of claim 28, wherein a germanium content of the silicon germanide alloy forming the extension is approximately 50 percent.

32. The method of claim 28, further comprising:
ion-implanting the extension with boron.
